(19) United States
(12) Patent Application Publication
(10) Pub. No.: US 2008/0135951 A1
(43) Pub. Date: Jun. 12, 2008

(54) Semiconductor Device and Method of Forming the Same

(75) Inventor: Vidya Kaushik, Hoeilaart (BE)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC, Austin, TX (US)

(21) Appl. No.: 11/575,721

(22) PCT Filed: Sep. 21, 2004
(86) PCT No.: PCT/EP04/52253

§ 371 Date: Mar. 21, 2007

(51) Int. Cl. H01L 21/336; H01L 29/78

(52) U.S. Cl. 257/410; 438/287; 257/E29.255; 257/E21.409

(57) ABSTRACT

It is known to provide a reoxidation step in the manufacture of a MOSFET that serves a number of structural purposes in relation to the MOSFET. However, the need to provide materials of high dielectric constant for gate insulator layers of MOSFETs to accommodate a drive for smaller integrated circuits has led to excessive growth of an SiO₂ interfacial layer between the gate insulator layer and a substrate. Excessive growth of the SiO₂ layer results in an Effective Oxide Thickness that leads to increased leakage current in the MOSFET. Further, the replacement of polysilicon with metals as electrodes precludes oxygen exposure during processing. Consequently, the present invention provides replacing or preceding the reoxidation step with the deposition of an oxygen barrier layer over at least side walls of a gate electrode of the MOSFET, thereby providing a barrier for oxygen diffusion to the dielectric interface and metal gate electrode that prevents EOT increase and preserves metal gate electrode integrity.

### FIELD OF THE INVENTION

The present invention relates to a method of forming a semiconductor device of the type, for example, comprising a barrier layer over at least side walls of a gate electrode, such as a Field Effect Transistor. The present invention also relates to a method of forming a semiconductor device of the type, for example, requiring the formation of a barrier layer, such as a Field Effect Transistor.

### BACKGROUND OF THE INVENTION

In the field of semiconductor devices, it is well known to form Metal Oxide Semiconductor Field Effect Transistors (MOSFETs) having a gate, source and drain. Typically, the gate is formed by depositing a layer of silicon dioxide (SiO₂), constituting a gate insulator layer, upon a silicon substrate and then depositing a polysilicon layer, constituting a gate electrode layer, upon the gate insulator layer. The gate electrode layer, and optionally the gate insulator layer is then etched to form an appropriately shaped gate. However, the gate insulator layer and the gate electrode layers do not always share the same profile.

As part of the processing of the MOSFET, a thermal treatment or anneal step in oxygen ambient is carried out, often referred to by technologists skilled in the field (and subsequently in this document) as a reoxidation step, typically at high temperature (greater than 700° C.), is carried out so as to deposit, or grow, a layer of silicon dioxide either over the side walls of the gate electrode and the top surface of the gate insulator layer, or if the gate insulator layer shares the same profile as the gate electrode layer, over the side walls of both the gate electrode layer and the gate insulator layer, and an upper surface of the silicon substrate.

The reoxidation step and the subsequently grown silicon dioxide layer serves a number of purposes, including acting as an etch-stop for a silicon nitride spacer, acting as a buffer layer between the gate electrode and a spacer deposition, and facilitating implantation of a drain region and a source region. The high temperature reoxidation step may also serve to anneal the gate, source and drain regions, thereby improving performance of the transistor.

In relation to integrated circuits, there is, of course, a constant drive to reduce the size of integrated circuits and this has led to a need to reduce the thickness of the gate insulator layer. However, forming thinner layers of silicon dioxide as the gate insulator layer leads to leakage, i.e. current flowing through the gate dielectric resulting in inefficient device power consumption.

Consequently, high dielectric constant materials, known as high-K dielectrics, based upon binary metal oxides and silicates are being employed to form part of the gate insulator layer, the gate insulator typically being formed from two sub layers: a high-K dielectric layer and a thinner silicon dioxide layer. The silicon dioxide layer lies between the high-K dielectric layer and the silicon substrate.

However, when the high-K dielectric layer is employed, it is difficult to carry out the reoxidation step, because high-K films are not good oxygen barriers, resulting in the silicon dioxide sub-layer, known as the interfacial layer, increasing in width, thereby degrading the so-called Equivalent Oxide Thickness (EOT) and hence reducing the capacitance across the insulating layer. Clearly, this decreases the performance of any MOSFET device comprising this structure.

Additionally, in the near future, polysilicon gate electrodes are likely to be replaced by metal or metal-like gate electrodes, such as gate electrodes formed from metal alloys or suicides of metals. Performing a conventional reoxidation step on a metal gate electrode may result in oxidisation of the metal, thereby compromising the integrity of the gate electrode. Thus, the reoxidation step cannot be performed with metal gate electrodes.

### STATEMENT OF INVENTION

In accordance with a first aspect of the present invention, there is provided a semiconductor device as set forth in the accompanying claims.

In accordance with a second aspect of the present invention, there is provided a field effect transistor as set forth in the accompanying claims.

In accordance with a third aspect of the present invention, there is provided a method of forming a semiconductor device as set forth in the accompanying claims.

Further aspects of the present invention are as claimed in the dependent Claims.

It is thus possible to provide a semiconductor device and method of forming a semiconductor device that provides the advantageous benefits of a silicon oxide layer formed by a reoxidation step, whilst avoiding the disadvantageous increase in the interfacial layer caused by the reoxidation step. Additionally, the aluminium oxide (or other related aluminium containing materials such as aluminium nitride, aluminium oxynitride, aluminium nitrided silicates or aluminium silicate, or any other suitable compounds containing aluminium, and at least one of: oxygen, nitrogen and/or silicon) layer can be disposed or deposited at relatively low temperatures in the range 250-400° C., thereby avoiding further increases in the EOT. The barrier layer is relatively simple to deposit in controllable thicknesses at low temperatures, as well as being a good oxygen barrier. The barrier layer is also resistant to ambients present in process steps subsequent to the deposition of the barrier layer and is easily etchable when needed. Consequently, if the benefits of the reoxidation step are deemed critical to device performance, the barrier layer allows the continued performance of a high temperature oxygen ambient anneal without compromising the dielectric EOT or the metal gate electrode. The provision of the barrier layer does not impede implantation of source and drain regions, dry or wet etching of the barrier layer being possible. The deposition of the barrier layer is also compatible with existing processing techniques.

### BRIEF DESCRIPTION OF THE DRAWINGS

At least one embodiment of the invention will now be described, by way of example only, with reference to the accompanying drawings, in which:

FIGS. 1 and 2 are schematic diagrams of initial common layers grown as part of a semiconductor device constituting an embodiment of the invention;

FIG. 3A is schematic diagram of processing of a gate electrode of a first common device structure;

FIG. 3B is a schematic diagram of processing of a gate electrode layer and an insulator layer of a second common device structure;

FIGS. 4A, and 4C are schematic diagrams of formation of a barrier layer for first and second device structures, respectively, based upon the first common device structure of FIG. 3A;

FIGS. 4B and 4D are schematic diagrams of formation of a barrier layer for third and fourth device structures, respectively, based upon the second common device structure of FIG. 3B;

FIGS. 5A and 5C are schematic diagrams of growth of a spacer for the first and second device structures of FIGS. 4A and 4C, respectively;

FIGS. 5B and 5D are schematic diagrams of growth of a spacer for the first and second device structures of FIGS. 4B and 4D, respectively;

FIGS. 5E and 5F are schematic diagrams of alternative structures to those of FIGS. 5C and 5D; and

FIG. 6 is a schematic diagram of the third device structure showing drain and source implantations.

### DESCRIPTION OF PREFERRED EMBODIMENTS

Throughout the following description identical reference numerals will be used to identify like parts.

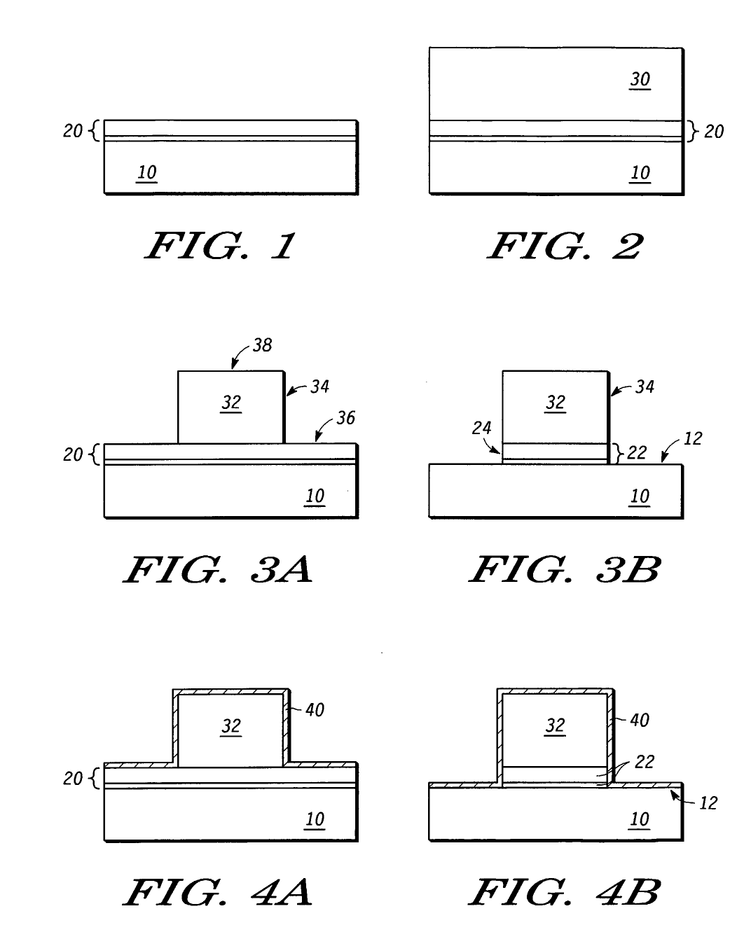

Referring to FIG. 1, a silicon substrate 10 is grown in accordance with a known Complementary Metal Oxide Semiconductor (CMOS) processing technique. Alternatively, the substrate could be a the Silicon On Insulator (SOI) substrate.

Using a known suitable deposition technique, a dielectric material, for example silicon dioxide (SiO₂), or typically a material with a dielectric constant greater than that of silicon, known as a high-K material, is then deposited as a gate insulator layer 20, on the substrate 10. The gate insulator layer 20 is grown to a thickness sufficient to constitute a high quality dielectric layer. Typically, the gate insulator layer 20 is grown to a thickness of between about 15 and 30 Angstroms depending on the dielectric constant of the material and the technological application.

However, it should be appreciated that the initial thickness of the gate insulator layer 20 can differ as well as the amount of etching required. The dielectric material used to form the gate insulator layer 20 may be deposited in one or more steps to eventually attain either a single dielectric layer or multiple layers.

The gate insulator layer 20 can therefore be considered as comprising sub-layers. Typically, the dielectric layer 20 consists of an interfacial layer containing silicon and oxygen and a higher-K material layer typically containing hafnium (Hf). In this example, the high-K material is hafnium oxide, but any other suitable high-K material can be used, for example zirconium oxide or aluminium oxide or any combination of hafnium oxide, zirconium oxide and aluminium oxide. The high-K material is, in this example, deposited using an Atomic Layer Deposition (ALD) technique, although other techniques, for example Physical Vapour Deposition (PVD), Chemical Vapour Deposition (CVD) or a combination thereof can be employed.

Thereafter (FIG. 2), a polysilicon (PolySi) or a metal gate electrode is deposited over the gate insulator 20 to form a gate electrode layer 30, one of two possible common structures can then be formed by using a suitable etching technique employed in known CMOS processing techniques.

In relation to a first common structure (FIG. 3A) for use in a first device structure and a second device structure, the gate electrode layer 30 is only etched initially to form a gate electrode 32 having exposed side walls 34, the gate insulator layer 20 having an exposed upper surface 36.

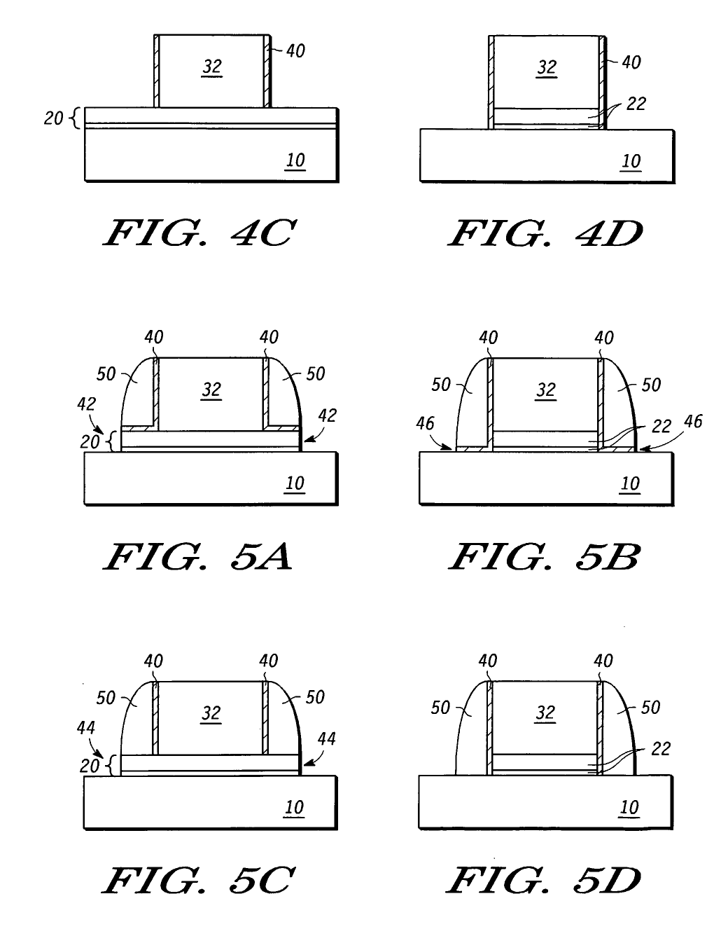

Referring to FIG. 4A, the first device structure is formed using an ALD, an aluminium oxide (Al₂O₃) barrier layer 40 (FIG. 4A) being formed over an upper surface 38 of the gate electrode 32, the side walls 34 of the gate electrode 20 and the upper surface 36 of the gate insulator layer 20.

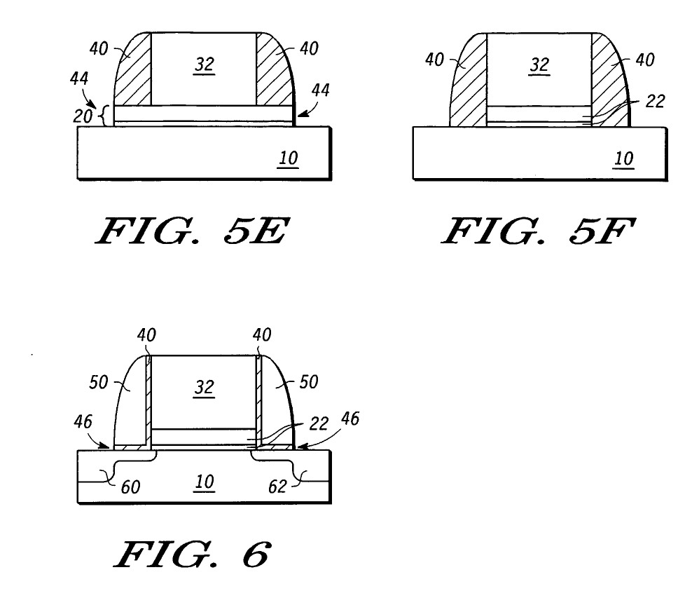

Turning to FIG. 5A, using known CMOS processing techniques, an uppermost part of the barrier layer 40 adjacent the upper surface 38 of the gate electrode 32 is then etched away and side portions of the gate insulator layer 20 and parts of the barrier layer disposed thereon are also etched away to expose and form a step 42 with the substrate 10 beneath the gate insulator layer 20 and the barrier layer 40. A spacer material is then deposited on the remaining part of the barrier layer 40 to form sidewall spacers 50.

In relation to the second device structure (FIG. 4C), and as an alternative to the first device structure, after deposition of the barrier layer 40, the barrier layer 40 is etched away from the upper surface 38 of the gate electrode 32 and the upper surface 36 of the gate insulator layer 20.

In common with the first device structure, and referring to FIG. 5C, side portions of the gate insulator layer 20 are etched to expose and form a step 44 with the substrate 10 beneath the gate insulator layer 20. The spacer material is then deposited on the remaining part of the gate insulating layer 20 adjacent the barrier layer 40 that covers the side walls 34 of the gate electrode 32 so as to form sidewall spacers 50.

Turning to FIG. 3B, a second common structure for use in relation to a third device structure and a fourth device structure differs from the first common structure in that the gate insulator layer 20 etched in addition to the gate electrode layer 30 so that a gate insulator 22, sharing the profile of the gate electrode 32, is created. Consequently, an upper surface 12 of the substrate 10 is exposed.

In relation to the third device structure (FIG. 4B), using an ALD step, the aluminium oxide barrier layer 40 is formed over the upper surface 38 of the gate electrode 32, the side walls 34 of the gate electrode 40, side walls 24 of the gate insulator 22 and the upper surface 12 of the substrate 10.

Using traditional CMOS processing techniques (FIG. 5B), an uppermost part of the barrier layer 40 adjacent the upper surface 38 of the gate electrode 32 is then etched away and side portions of the barrier layer 40 disposed upon the substrate 10 are also etched away to expose and form a step 46 with the substrate 10. A spacer material is then deposited on the remaining part of the barrier layer 40 to form the sidewall spacers 50.

In relation to the fourth device structure (FIG. 4D), and as an alternative to the third device structure, after deposition of the barrier layer 40, the barrier layer 40 is etched away from the upper surface 38 of the gate electrode 32 and the upper surface 12 of the substrate 10.

With respect to the above examples, the aluminium oxide (Al₂O₃) barrier liner or layer is deposited to a thickness of between about 5 to 10 nm. Deposition is by ALD at about 300° C. The barrier layer 40 serves as a good barrier to oxygen, thereby maintaining the effective oxide thickness of the gate insulator layer 20/gate insulator 22. The barrier layer 40 also preserves the metal gate electrode 32 from exposure to oxygen, since an oxygen anneal can adversely impact the metallic integrity of the gate electrode 32. Where appropriate, the barrier layer 40 can serve as a screen for implantation of source and drain regions, thereby eliminating a silicon dioxide deposition step.

In common with the third device structure, and referring to FIG. 5D, the spacer material is deposited on a region of the substrate 10 adjacent the remaining barrier layer 40 that covers the side walls 24, 34 of the gate electrode 40 and the gate insulator 22 so as to form the sidewall spacers 50.

In an alternative embodiment (FIG. 5E) to that of the first device structure, instead of growing the aluminium oxide barrier layer 40 and the sidewall spacer 50, aluminium oxide is deposited and profiled so as to server as both an oxygen barrier and the sidewall spacer 50.

Similarly, in an alternative embodiment (FIG. 5F) to that of the third device structure, instead of growing the aluminium oxide barrier layer 40 and the sidewall spacer 50, aluminium oxide is also deposited and profiled so as to server as both an oxygen barrier and the sidewall spacer 50.

Turning to FIG. 6, in relation to the third device structure, a source region 60 and a drain region 62 are respectively implanted into the substrate either side of the gate insulator 22 and the gate electrode 32 in accordance with known CMOS processing techniques. Indeed, the device is completed in accordance with the traditional CMOS processing techniques.

It should, of course, be appreciated that implantation of source and drain regions as well as completion of the first, second and fourth device structures is in a like manner to that described above in relation to the third device structure.

Whilst in the above examples reference has been made to the gate electrode 32 and the gate insulator 22, it should be appreciated that these are, nevertheless, considered to be layers.

1. A semiconductor device comprising:
a substrate;
a gate insulator layer comprising a sub-layer of a high dielectric constant material disposed adjacent a silicon dioxide layer, the silicon dioxide layer being located adjacent the substrate;
a gate electrode layer disposed upon the gate insulator layer comprising:
an oxygen barrier layer is disposed over at least side walls of the gate electrode.

2. A device as claimed in claim 1, wherein the oxygen barrier layer is disposed over side walls of the gate insulator layer.

3. A device as claimed in claim 1, wherein the gate electrode layer has the oxygen barrier layer disposed thereon.

4. A device as claimed in claim 1, wherein the high dielectric constant material is one or a combination of: hafnium oxide, zirconium oxide or aluminium.

5. A device as claimed in claim 1, wherein a spacer material is disposed adjacent the oxygen barrier layer.

6. A device as claimed in claim 1, wherein the oxygen barrier layer is a compound containing aluminium and at least one of: oxygen, nitrogen and/or silicon.

7. A device as claimed in claim 5, wherein the oxygen barrier layer is disposed sufficiently thickly and is appropriately shaped to serve as the spacer.

8. A field effect transistor comprising the semiconductor device as claimed in claim 1.

9. A transistor as claimed in claim 8, wherein the field effect transistor is a metal oxide semiconductor field effect transistor.

10. A method of forming a semiconductor device, the method comprising the steps of:
forming a substrate;
disposing a gate insulator layer upon the substrate, the gate insulator layer comprising a sub-layer of a high dielectric constant material disposed adjacent a silicon dioxide layer, the silicon dioxide layer being located adjacent the substrate;
disposing a gate electrode layer upon the gate insulator layer; and
disposing an oxygen barrier layer over at least the side walls of the gate electrode layer.

11. A method as claimed in claim 10, wherein the step of depositing the oxygen barrier layer over at least the side walls of the gate electrode layer further comprises the step of:
depositing the oxygen barrier layer over side walls of the gate insulator layer.

12. A method as claimed in claim 10, wherein the step of depositing the oxygen barrier layer over at least the side walls of the gate electrode layer further comprises the step of:
depositing the oxygen barrier layer upon the gate electrode layer.

13. A method as claimed in claim 10, further comprising the step of:
depositing a spacer material adjacent the oxygen barrier layer.

14. A method as claimed in claim 13, further comprising the step of:
depositing the oxygen barrier layer sufficiently thickly and appropriately shaping the oxygen barrier layer to serve as the spacer.

15. A method as claimed in claim 10, wherein the oxygen barrier layer is a compound containing aluminium and at least one of: oxygen, nitrogen and/or silicon.
